(19) United States
(12) Patent Application Publication
(10) Pub. No.: US 2026/0159380 A1
(43) Pub. Date: Jun. 11, 2026

(54) METHODS FOR FORMING AN OPTICAL PACKAGE

(71) Applicant: Infineon Technologies AG, Neubiberg (DE)

(72) Inventors: Markus BAINSCHAB, Villach (AT); André BROCKMEIER, Villach (AT); Dirk MEINHOLD, Dresden (DE)

(21) Appl. No.: 19/296,628

(22) Filed: Aug. 11, 2025

(30) Foreign Application Priority Data
Aug. 27, 2024 (DE) 102024124469.0

(51) Int. Cl. B81C 1/00; G02B 26/10

(52) U.S. Cl. CPC B81C 1/00317; B81C 1/00634; G02B 26/10

(57) ABSTRACT

A method for forming an optical package includes forming a patterned hard mask on a surface of a semiconductor wafer. The patterned hard mask includes a plurality of recesses defining positions of cavities to be formed in the semiconductor wafer. Additionally, the method includes forming a respective photoresist structure on the surface of the semiconductor wafer in the plurality of recesses. The method further includes performing a first etch process during which the semiconductor wafer is etched in the recesses at positions not covered by the photoresist structure. In addition, the method includes removing the photoresist structures after performing the first etch process and performing a second etch process after removing the photoresist structures. In the second etch process, the semiconductor wafer is etched in the recesses to form the cavities by lowering structures formed in the first etch process.

### CROSS REFERENCE TO RELATED APPLICATION

This application claims priority to Germany Patent Application No. 102024124469.0 filed on Aug. 27, 2024, the content of which is incorporated by reference herein in its entirety.

### TECHNICAL FIELD

The present disclosure relates to forming of optical packages. In particular, examples of the present disclosure relate to methods for forming an optical package.

### BACKGROUND

Wafer-level glass blowing constitutes a cost-effective method to fabricate optical wafer-level packages for Micro-Electro-Mechanical System (MEMS) devices such as laser beam scanners. A silicon wafer is structured using Deep Reactive Ion Etching (DRIE) to create cavities that are typically of elliptic or circular shape with diameters of a few millimeters and a depth of a few hundred micrometers. The structured silicon wafer is irreversible bonded to a glass wafer under defined conditions. The bonded wafer stack is heated to temperatures close to the softening point of the glass in a furnace process. At the elevated temperatures, the glass viscosity decreases and the pressure of the gas encapsulated in the cavities increases. Dome-shaped glass structures are formed above the cavities. By either opening the cavities in the silicon wafer or removing the silicon wafer completely from the glass wafer and another wafer bonding process, the dome structures act as an optical wafer-level package for MEMS structures.

The depths of the DRIE cavities substantially vary over the wafer. This uniformity variation is typically tool/equipment related (e.g., chamber geometry, showerhead configuration, chuck configuration with respect to biasing). A cavity depth increase at the wafer edge compared to the wafer center can be observed typically. With the increased volume of the cavities associated with the increased depth, also the final height of the blown-out dome structures increase by a similar relative amount from wafer center to edge. The dome height spread causes collisions inside fabrication tools during subsequent processing steps. Furthermore, the dome height has an impact on the optical properties of the package. To minimize optical aberrations, the dome's center of curvature at the apex should be equal to the distance of the dome apex to the MEMS mirror surface. With the spread of the dome heights across one wafer this condition is substantially violated for a large number of devices. This violation translates to a significant yield loss.

Hence, there may be a demand for improved forming of optical packages.

### SUMMARY

This demand is met by the subject-matter of the independent claims. Advantageous implementations are addressed by the dependent claims.

According to a first aspect, the present disclosure provides a method for forming an optical package. The method includes forming a patterned hard mask on a surface of a semiconductor wafer. The patterned hard mask includes a plurality of recesses defining positions of cavities to be formed in the semiconductor wafer. Additionally, the method includes forming a respective photoresist structure on the surface of the semiconductor wafer in the plurality of recesses. A size of the surface area covered by the respective photoresist structure in the respective recess is dependent on a position of the respective recess on the semiconductor wafer. The method further includes performing a first etch process. In the first etch process, the semiconductor wafer is etched in the recesses at positions not covered by the photoresist structure. In addition, the method includes removing the photoresist structures after performing the first etch process and performing a second etch process after removing the photoresist structures. In the second etch process, the semiconductor wafer is etched in the recesses to form the cavities by lowering structures formed in the first etch process.

According to a second aspect, the present disclosure provides another method for forming an optical package. The method includes forming a patterned masking layer on a surface of a semiconductor wafer. The patterned masking layer includes a plurality of recesses defining positions of cavities to be formed in the semiconductor wafer. In addition, the method includes performing a first etch process. In the first etch process, the semiconductor wafer is etched in the plurality of recesses to form hollows in the surface of the semiconductor wafer. The method includes removing the patterned masking layer. Further, the method includes forming a photoresist structure after removing the patterned masking layer. The photoresist structure partly covers the surface of the semiconductor wafer in the hollows. A size of the surface area covered by the photoresist structure in the respective hollow is dependent on a position of the respective hollow in the semiconductor wafer. Additionally, the method includes performing a second etch process. In the second etch process, the semiconductor wafer is etched in the hollows at positions not covered by the photoresist structure to form the cavities.

By varying the size of the photoresist structures in the method according to the first aspect and by varying the size of the surface area covered by the photoresist structure in the respective hollow in the method according to the second aspect, the methods compensate for potential etching depth variations across the semiconductor wafer, in particular from the center to the edge of the wafer, leading to (more) uniform cavity depths. The methods allow to achieve (more) uniform cavity depths across the wafer which is beneficial for the consistent performance of the optical devices packaged within these cavities. Accordingly, the yield may be increased. Overall, the methods allow to create well-defined cavities in semiconductor wafers, which is beneficial for high-precision optical packages used in various technological applications.

### BRIEF DESCRIPTION OF THE DRAWINGS

Some examples of apparatuses and/or methods will be described in the following by way of example only, and with reference to the accompanying figures, in which

FIG. 1 illustrates a flowchart of an example of a first method for forming an optical package;

FIGS. 2A-2D illustrate a semiconductor wafer during different stages of a first implementation variant of the first method for forming an optical package;

FIGS. 3A-3D illustrate a semiconductor wafer during different stages of a second implementation variant of the first method for forming an optical package;

FIG. 4 illustrates an example of a semiconductor wafer with formed cavities;

FIG. 5 illustrates the forming of dome-shaped structures;

FIG. 6 illustrates a comparison of the variation of the relative volumes of the cavities across the semiconductor wafer between the first method and a conventional method;

FIG. 7 illustrates a flowchart of an example of a second method for forming an optical package; and

FIGS. 8A-8F illustrate a semiconductor wafer during different stages of the second method for forming an optical package.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

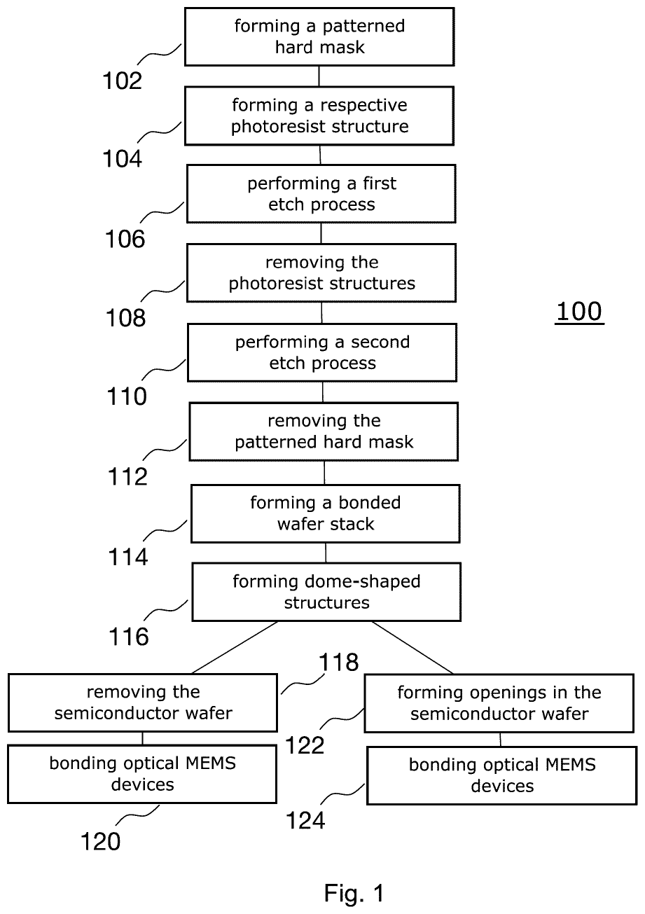

FIG. 1 illustrates a flowchart of a method 100 for forming an optical package.

The method 100 comprises forming 102 a patterned hard mask on a surface of a semiconductor wafer. The patterned hard mask comprises a plurality of recesses defining positions of cavities to be formed in the semiconductor wafer.

The semiconductor wafer is a thin, typically circular piece of semiconductor material which serves as a foundational platform. The semiconductor material may, e.g., be silicon. The diameter of the semiconductor wafer may, e.g., be between approx. 100 mm and approx. 300 mm, in particular 200 mm. A thickness of the semiconductor wafer may, e.g., be between 400 μm and 1000 μm, in particular 600 μm. It is to be noted that the present disclosure is not limited to the foregoing example material and dimensions of the semiconductor wafer. Other suitable semiconductor materials and dimensions may be used as well.

The patterned hard mask is a layer of material used to pattern the cavities on the substrate. The cavities are recessed areas (recesses, hollows) to be formed in the semiconductor wafer. The multiple recesses indicate where the cavities are to be formed (will be formed) in the wafer. For example, the patterned hard mask may be made of a durable material such as dielectric materials like silicon nitride (Si3N4) or silicon dioxide (SiO2), or metals like titanium or tungsten such that the patterned hard mask is not light-sensitive like a photoresist. Forming 102 the patterned hard mask may, e.g., comprise depositing hard mask material onto the semiconductor wafer, applying a layer of photoresist on the hard mask material, patterning the photoresist using a photomask that comprises the desired pattern that defines where the cavities will be formed, developing the photoresist to remove the exposed or unexposed areas of the photoresist (depending on the type of photoresist) and reveal the pattern of the hard mask material beneath, etching away the exposed hard mask material to transfer the pattern from the photoresist to the hard mask material and stripping away the remaining photoresist such that the pattern hard mask is left on the semiconductor wafer. A thickness of the patterned hard mask may, e.g., be between 0.5 μm and 10 μm, in particular 2.5 μm.

Additionally, the method 100 comprises forming 104 a respective photoresist structure on the surface of the semiconductor wafer in the plurality of recesses. A size of the surface area covered by the respective photoresist structure in the respective recess is dependent on a position of the respective recess on the semiconductor wafer. In other words, photoresist structures are formed on the semiconductor wafer's surface within the recesses of the hard mask. The size of each photoresist structure varies based on its position on the wafer. The photoresist structures are made of a light-sensitive material that undergoes chemical changes when exposed to light. For example, positive photoresist or negative photoresist may be used. Forming 104 the respective photoresist structure may, e.g., comprise applying photoresist material, soft baking the applied photoresist material, patterning the photoresist material using a photomask that comprises the desired pattern that defines where the photoresist structures will be formed, developing the photoresist to remove the exposed or unexposed areas of the photoresist (depending on the type of photoresist) and reveal the areas of the semiconductor wafer that are to be etched.

The method 100 further comprises performing 106 a first etch process (first etching process). In the first etch process, the semiconductor wafer is etched in the recesses at positions not covered by the photoresist structure. The photoresist structures define the areas of the semiconductor wafer that are exposed by the recesses in the patterned hard mask and are protected during the first etch process. Areas of the semiconductor wafer's surface not covered by the patterned hard mask and the photoresist structures are etched to a certain depth in the first etch process. For example, DRIE may be used in the first etch process for etching the semiconductor wafer.

In addition, the method 100 comprises removing 108 the photoresist structures after performing the first etch process. The photoresist structures may be removed using various techniques such as chemical stripping, plasma ashing or wet chemical etching. After removing 108 the photoresist structures, the areas of the semiconductor wafer that were protected during the first etch process are exposed.

The method 100 comprises performing 110 a second etch process (second etching process) after removing the photoresist structures. In the second etch process, the semiconductor wafer is etched in the recesses to form the cavities by lowering structures formed in the first etch process. In other words, the cavities are further etched in the semiconductor wafer during the second etch process based on the initial structures formed during the first etch. For example, DRIE may be used in the second etch process for etching the semiconductor wafer.

By varying the size of the photoresist structures, the method 100 compensates for potential etching depth variations across the semiconductor wafer, in particular from the center (central region) to the edge (peripheral boundary or outermost part) of the semiconductor wafer, leading to (more) uniform cavity depths. The depths of the cavities refers to the vertical distance from the surface of the semiconductor wafer to the bottom of the etched cavities. The method 100 allows to achieve (more) uniform cavity depths across the semiconductor wafer which is beneficial for the consistent performance of the optical devices packaged within these cavities. For example, the depths of the cavities may differ by less than 15% or less than 10% from each other across the semiconductor wafer. In particular, the depths of the cavities may differ by less than 15% or less than 10% particular from the center to the edge of the semiconductor wafer. The depths of the cavities may be at least 20%, 25% or 30% and at maximum 75%, 80% or 85% of the thickness of the semiconductor wafer. For example, if the thickness of the semiconductor wafer is between 400 μm and 1000 μm, the depths of the cavities may be between 100 and 600 μm, in particular 400 μm, with a depth variation of less 15% or less than 10% across the semiconductor wafer (in particular from the center to the edge of the semiconductor wafer). Overall, the method 100 allows to create well-defined cavities in semiconductor wafers, which is beneficial for high-precision optical packages used in various technological applications.

The plurality of recesses in the patterned hard mask may exhibit the same dimensions. In other words, all recesses may have uniform dimensions in terms of form (shape), size and depth. Accordingly, the cavities may be formed with uniform dimensions in terms of shape and size. For example, the plurality of recesses may exhibit a circular form or an elliptic form. Accordingly, the cavities may exhibit a circular form or an elliptic form. However, the present disclosure is not limited thereto. The recesses may in general exhibit any form. The lateral extension (e.g., the horizontal dimension or width) of the respective cavity in the semiconductor wafer may be between 3 mm and 10 mm, in particular 5 mm.

According to examples of the present disclosure, the size of the surface area covered by the respective photoresist structure in the respective recess may vary from the center to the edge of the semiconductor wafer. In other words, the size of the photoresist-covered area is not uniform across the semiconductor wafer. Instead, it changes progressively across the semiconductor wafer (e.g., from the center of the semiconductor wafer to its edge). In particular, the size of the surface area covered by the respective photoresist structure in the respective recess may vary from the center to the edge of the semiconductor wafer to compensate the etching depth variation from the center to the edge of the semiconductor wafer in the first and the second etch process. By varying the photoresist coverage, the method 100 compensates for variations in etching depth that naturally occur from the center to the edge of the semiconductor wafer. This ensures more uniform cavity depths across the entire semiconductor wafer. The size of the surface area covered by the respective photoresist structure in the respective recess may, e.g., increase from the center to the edge of the semiconductor wafer. In other words, the surface area covered by the photoresist structures in the recesses increases as one moves from the center of the semiconductor wafer towards its edge. This variation compensates for typically faster etching rates at the semiconductor wafer edge, ensuring uniform cavity depths.

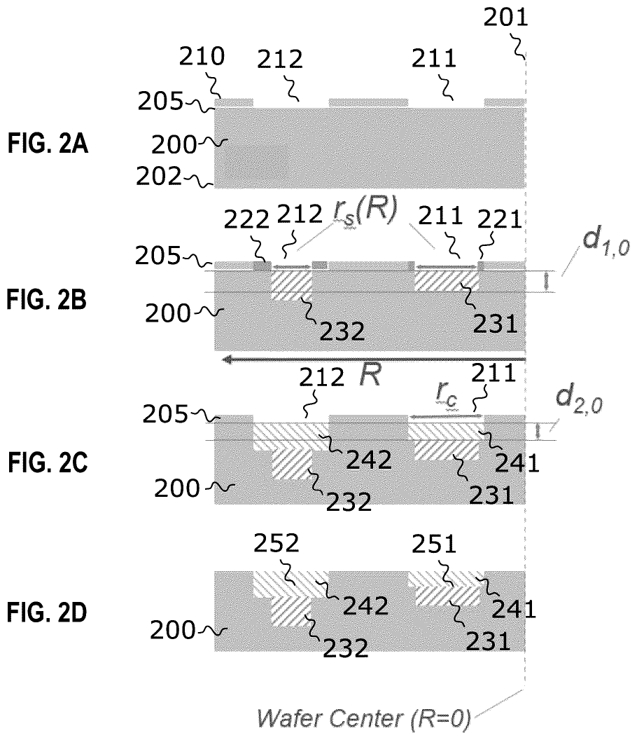

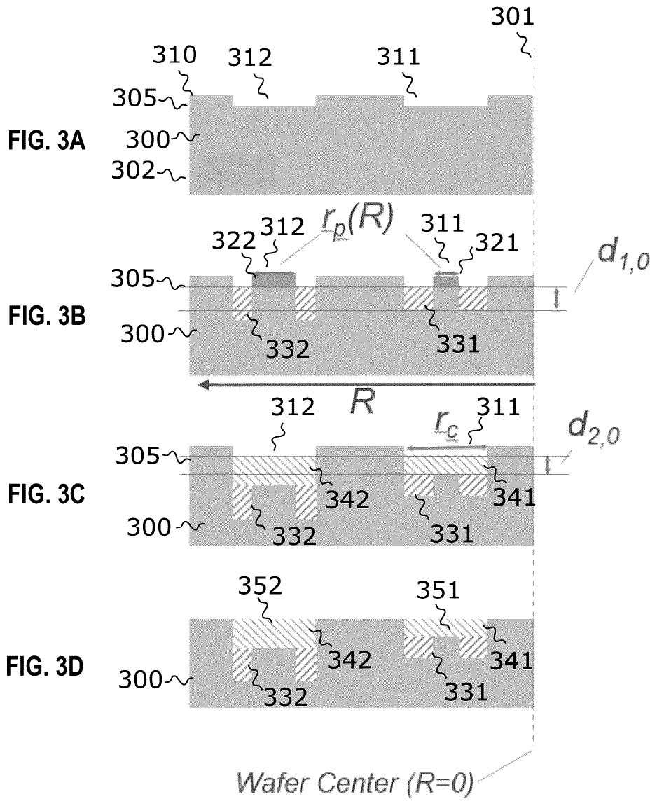

Further details of the method 100 will be described in the following with reference to FIGS. 2A-2D and FIGS. 3A-3D showing a semiconductor wafer during different stages of two implementation variants of the method 100.

FIGS. 2A-2D illustrate a semiconductor wafer 200 during different stages of a first implementation variant of the method 100. FIGS. 2A-2D illustrate a sectional view through one half of the semiconductor wafer 200. The dashed line 201 indicates the center of the semiconductor wafer 200 (with a radial distance R=0). The other half of the semiconductor wafer 200 is symmetric and, hence, not shown.

As shown in subfigure (a), the patterned hard mask 210 is initially formed on the surface 205 of the semiconductor wafer 200. For reasons of simplicity, the patterned hard mask 210 comprises only two recesses 211 and 212. However, it is to be noted that the present disclosure is not limited thereto. Any number N≥2 of recesses may be formed in the patterned hard mask 210. The recess 211 is closer to the center of the semiconductor wafer 200 than the recess 212. The recess 212 is closer to the edge 202 of the semiconductor wafer 200 than the recess 211. The recesses 211 and 212 exhibit a circular form and the same dimensions in the example of FIGS. 2A-2D. In particular, the radius re of both recesses 211 and 212 is constant (the same).

Then, as shown in subfigure (b), a respective photoresist structure 221, 222 is formed on the surface 201 of the semiconductor wafer 200 in the recesses 211 and 212. The photoresist structures 221 and 222 are formed at boundaries of the recesses 211 and 212. The photoresist structures 221 and 222 contact the patterned hard mask 210 along the entire respective boundary. The photoresist structures 221 and 222 do not cover the semiconductor wafer 200 in the centers of the recesses 211 and 212. The inner contours of the photoresist structures 221 and 222 exhibit the same shape as the boundaries of the recesses 211 and 212. As the recesses 211 and 212 exhibit a circular form, the photoresist structures 221 and 222 are annular rings in the example of FIGS. 2A-2D.

As can be seen from subfigure (b), the size of the surface area covered by the respective photoresist structure 221, 222 in the respective recess 211, 212 is dependent on the position of the respective recess 211, 212 on the semiconductor wafer 200. In particular, the size of the surface area covered by the respective photoresist structure 221, 222 in the respective recess 211, 212 increases from the center to the edge of the semiconductor wafer 200. The photoresist structure 222 covers more of the surface area in the recess 212 than the photoresist structure 221 covers in the recess 211.

The surface area in the respective recess 211, 212 not covered by the respective photoresist structure 221, 222 decreases from the center to the edge of the semiconductor wafer 200. The surface area Aₛ in the respective recess 211, 212 not covered by the respective photoresist structure 221, 222 depends on the radial distance R to the center of the semiconductor wafer 200 and is defined as follows:

$${A}_{s} ( R ) = π \cdot {r}_{s}^{2} ( R ) \qquad ( 1 )$$

with rₛ denoting the radius of the respective surface area Aₛ in the respective recess 211, 212 not covered by the respective photoresist structure 221, 222.

Then, as further shown in subfigure (b), the first etch process is performed to etch the semiconductor wafer 200 in the recesses 211 and 212 at the positions in the center not covered by the photoresist structures 221 and 222. For example, DRIE may be used for etching the semiconductor wafer 200 in the first etch process. A first part of the respective cavity is formed in the first etch process by removing part of the semiconductor wafer 200 at the positions in the center not covered by the photoresist structures 221 and 222. The parts of the semiconductor wafer 200 etched away in the first etch process are denoted by reference signs 231 and 232. A cylindrical first sub-cavity is formed in each of the recesses 211 and 212 in the first etch process.

As indicated in subfigure (b), the depths of the structures formed in the first etch process are not uniform across the semiconductor wafer 200. The depths of the structures formed in the first etch process depend on the radial distance R to the center of the semiconductor wafer 200. In particular, the depth increases with increasing radial distance R to the center of the semiconductor wafer 200. The structure formed at the center of the recess 212 not covered by the photoresist structure 222 is deeper than the structure formed at the center of the recess 211 not covered by the photoresist structure 221. This may be expressed as follows:

$${d}_{1} ( R ) = {d}_{1 , 0} \cdot {d}_{etch} ( R ) \qquad ( 2 )$$

with d₁(R) denoting the depth of the structure formed in the first etch process at a specific radial distance R to the center of the semiconductor wafer 200, d_{1,0} denoting a constant reference depth at the center of the semiconductor wafer (e.g., d_{1,0}=d₁(R=0)) and d_{etch}(R) denoting a scaling function that depends on the radial distance R to the center of the semiconductor wafer 200. The value of the scaling function increases with increasing radial distance R to the center of the semiconductor wafer 200.

Then, after performing the first etch process, the photoresist structures 221 and 222 are removed. After removing the photoresist structures 221 and 222, the second etch process is performed. This is illustrated in subfigure (c). For example, DRIE may be used for etching the semiconductor wafer 200 in the second etch process. In the second etch process, the semiconductor wafer 200 is etched in the recesses 211 and 212 to form the cavities by lowering the structures formed in the first etch process. Accordingly, a second part of the respective cavity is formed in the second etch process by removing part of the semiconductor wafer 200 in the recesses 211 and 212. The parts of the semiconductor wafer 200 etched away in the second etch process are denoted by reference signs 241 and 242. A cylindrical second sub-cavity is formed in each of the recesses 211 and 212 in the second etch process.

As indicated in subfigure (c), the depths of the structures formed in the second etch process are not uniform across the semiconductor wafer 200. The depths of the structures formed in the second etch process depend on the radial distance R to the center of the semiconductor wafer 200. In particular, the depth increases with increasing radial distance R to the center of the semiconductor wafer 200. The structure formed in the recess 212 is deeper than the structure formed in the recess 211. This may be expressed as follows:

$${d}_{2} ( R ) = {d}_{2 , 0} \cdot {d}_{etch} ( R ) \qquad ( 3 )$$

with d₂(R) denoting the depth of the structure formed in the second etch process at a specific radial distance R to the center of the semiconductor wafer 200 and d_{2,0} denoting a constant reference depth at the center of the semiconductor wafer (e.g., d_{2,0}=d₂(R=0)).

The resulting cavities 251 and 252 are shown in subfigure (d). The cavity 252 is deeper than the cavity 251. The volume V of each cavity may be expressed as follows:

$$V = π \cdot {r}_{s}^{2} ( R ) \cdot {d}_{1} ( R ) + π \cdot {r}_{c}^{2} \cdot {d}_{2} ( R ) \qquad ( 4 )$$

This may be re-written as follows based on mathematical expressions (3) and (4):

$$V = π \cdot {r}_{s}^{2} ( R ) \cdot {d}_{1 , 0} \cdot {d}_{etch} ( R ) + π \cdot {r}_{c}^{2} \cdot {d}_{2 , 0} \cdot {d}_{etch} ( R ) \qquad ( 5 )$$

$$V = π \cdot {d}_{etch} ( R ) \cdot ( {r}_{s}^{2} ( R ) \cdot {d}_{1 , 0} + {r}_{c}^{2} \cdot {d}_{2 , 0} ) \qquad ( 6 )$$

$$\frac{V}{π \cdot {d}_{e t c h} ( R )} = {r}_{s}^{2} ( R ) \cdot {d}_{1 , 0} + {r}_{c}^{2} \cdot {d}_{2 , 0} \qquad ( 7 )$$

$$\frac{V}{π \cdot {d}_{e t c h} ( R )} - {r}_{c}^{2} \cdot {d}_{2 , 0} = {r}_{s}^{2} ( R ) \cdot {d}_{1 , 0} \qquad ( 8 )$$

$${r}_{s}^{2} ( R ) = \frac{1}{{d}_{1 , 0}} \cdot ( \frac{V}{π \cdot {d}_{e t c h} ( R )} - {r}_{c}^{2} \cdot {d}_{2 , 0} ) \qquad ( 9 )$$

$${r}_{s} ( R ) = \sqrt{\frac{1}{{d}_{10}} \cdot ( \frac{V}{π \cdot {d}_{e t c h} ( R )} - {r}_{c}^{2} \cdot {d}_{2 , 0} )} \qquad ( 10 )$$

The parameters V and re are predefined target parameters. The parameters d_{1,0}, d_{2,0} and d_{etch}(R) can be measured. Hence, mathematical expression (10) allows to determine the radius of the respective surface area Aₛ in the respective recess 211, 212 not covered by the respective photoresist structure 221, 222.

In the example of FIGS. 2A-2D, the etching depth variation is compensated by structuring cavities with smaller diameters. The cavity structures formed in the first etching step are radius dependent. The step-like structure etched in the example of FIGS. 2A-2D creates cavities of varying diameters after opening the cavities from the wafer back. The fact that during the opening process no structures are released may reduce the defect density.

FIGS. 3A-3D illustrate a semiconductor wafer 300 during different stages of an alternative second implementation variant of the method 100. FIGS. 3A-3D illustrate a sectional view through one half of the semiconductor wafer 300. The dashed line 301 indicates the center of the semiconductor wafer 300 (with a radial distance R=0). The other half of the semiconductor wafer 300 is symmetric and, hence, not shown.

As shown in subfigure (a), the patterned hard mask 310 is initially formed on the surface 305 of the semiconductor wafer 300. For reasons of simplicity, the patterned hard mask 310 comprises only two recesses 311 and 312. However, it is to be noted that the present disclosure is not limited thereto. Any number N≥2 of recesses may be formed in the patterned hard mask 310. The recess 311 is closer to the center of the semiconductor wafer 300 than the recess 312. The recess 312 is closer to the edge 302 of the semiconductor wafer 300 than the recess 311. The recesses 311 and 312 exhibit a circular form and the same dimensions in the example of FIGS. 3A-3D. In particular, the radius r_{c} of both recesses 311 and 312 is constant (the same).

As can be seen from subfigure (b), the size of the surface area covered by the respective photoresist structure 321, 322 in the respective recess 311, 312 is dependent on the position of the respective recess 311, 312 on the semiconductor wafer 300. In particular, the size of the surface area covered by the respective photoresist structure 321, 322 in the respective recess 311, 312 increases from the center to the edge of the semiconductor wafer 300. The photoresist structure 322 covers more of the surface area in the recess 312 than the photoresist structure 321 covers in the recess 311.

The surface area in the respective recess 311, 3212 not covered by the respective photoresist structure 321, 322 decreases from the center to the edge of the semiconductor wafer 200. The surface area Aₚ in the respective recess 311, 312 not covered by the respective photoresist structure 321, 322 depends on the radial distance R to the center of the semiconductor wafer 200 and is defined as follows:

$${A}_{p} ( R ) = π \cdot ( {r}_{c}^{2} - {r}_{p}^{2} ( R ) ) \qquad ( 11 )$$

with rₚ denoting the radius of the respective surface area in the respective recess 211, 212 covered by the respective photoresist structure 221, 222.

Then, as further shown in subfigure (b), the first etch process is performed to etch the semiconductor wafer 300 in the recesses 311 and 312 at the positions in the boundary not covered by the photoresist structures 321 and 322. For example, DRIE may be used for etching the semiconductor wafer 300 in the first etch process. A first part of the respective cavity is formed in the first etch process by removing part of the semiconductor wafer 300 at the positions in the boundary not covered by the photoresist structures 321 and 322. The parts of the semiconductor wafer 300 etched away in the first etch process are denoted by reference signs 331 and 332. A ring-shaped first sub-cavity is formed in each of the recesses 311 and 312 in the first etch process. The ring-shaped first sub-cavity encloses a respective pillar in the center of each of the recesses 311 and 312.

As indicated in subfigure (b), the depths of the structures formed in the first etch process are not uniform across the semiconductor wafer. The depths of the structures formed in the first etch process depend on the radial distance R to the center of the semiconductor wafer 300. In particular, the depth increases with increasing radial distance R to the center of the semiconductor wafer 300. The ring-shaped structure formed at the boundary of the recess 312 not covered by the photoresist structure 322 is deeper than the ring-shaped structure formed at the boundary of the recess 311 not covered by the photoresist structure 321. The depths may be expressed analogously to above mathematical expression (2).

Then, after performing the first etch process, the photoresist structures 321 and 322 are removed. After removing the photoresist structures 321 and 322, the second etch process is performed. This is illustrated in subfigure (c). For example, DRIE may be used for etching the semiconductor wafer 300 in the second etch process. In the second etch process, the semiconductor wafer 300 is etched in the recesses 311 and 312 to form the cavities by lowering the structures formed in the first etch process. Accordingly, a second part of the respective cavity is formed in the second etch process by removing part of the semiconductor wafer 300 in the recesses 311 and 312. The parts of the semiconductor wafer 200 etched away in the second etch process are denoted by reference signs 341 and 342. A cylindrical second sub-cavity is formed in each of the recesses 311 and 312 in the second etch process.

As indicated in subfigure (c), the depths of the structures formed in the second etch process are not uniform across the semiconductor wafer 300. The depths of the structures formed in the second etch process depend on the radial distance R to the center of the semiconductor wafer 300. In particular, the depth increases with increasing radial distance R to the center of the semiconductor wafer 300. The structure formed in the recess 312 is deeper than the structure formed in the recess 311. The depths may be expressed analogously to above mathematical expression (2).

The resulting cavities 351 and 352 are shown in subfigure (d). The cavity 352 is deeper than the cavity 351. The volume V of each cavity may be expressed as follows:

$$V = π \cdot ( {r}_{c}^{2} - {r}_{p}^{2} ( R ) ) \cdot {d}_{1} ( R ) + π \cdot {r}_{c}^{2} \cdot {d}_{2} ( R ) \qquad ( 12 )$$

This may be re-written as follows based on the analogues of mathematical expressions (3) and (4):

$$V = π \cdot ( {r}_{c}^{2} - {r}_{p}^{2} ( R ) ) \cdot {d}_{1 , 0} \cdot {d}_{etch} ( R ) + π \cdot {r}_{c}^{2} \cdot {d}_{2 , 0} \cdot {d}_{etch} ( R ) \qquad ( 13 )$$

$$V = π \cdot {d}_{etch} ( R ) \cdot ( ( {r}_{c}^{2} - {r}_{p}^{2} ( R ) ) \cdot {d}_{1 , 0} + {r}_{c}^{2} \cdot {d}_{2 , 0} ) \qquad ( 14 )$$

$$\frac{V}{π \cdot {d}_{e t c h} ( R )} = ( {r}_{c}^{2} - {r}_{p}^{2} ( R ) ) \cdot {d}_{1 , 0} + {r}_{c}^{2} \cdot {d}_{2 , 0} \qquad ( 15 )$$

$$\frac{V}{π \cdot {d}_{e t c h} ( R )} = - {r}_{p}^{2} ( R ) \cdot {d}_{1 , 0} + {r}_{c}^{2} ( {d}_{1 , 0} + {d}_{2 , 0} ) \qquad ( 16 )$$

$${r}_{c}^{2} ( {d}_{1 , 0} + {d}_{2 , 0} ) - \frac{V}{π \cdot {d}_{e t c h} ( R )} = {r}_{p}^{2} ( R ) \cdot {d}_{1 , 0} \qquad ( 17 )$$

$${r}_{p}^{2} ( R ) = \frac{1}{{d}_{1 , 0}} \cdot ( {r}_{c}^{2} ( {d}_{1 , 0} + {d}_{2 , 0} ) - \frac{V}{π \cdot {d}_{e t c h} ( R )} ) \qquad ( 18 )$$

$${r}_{p} ( R ) = \sqrt{\frac{1}{{d}_{1 , 0}} \cdot ( {r}_{c}^{2} ( {d}_{1 , 0} + {d}_{2 , 0} ) - \frac{V}{π \cdot {d}_{e t c h} ( R )} )} \qquad ( 19 )$$

Like mathematical expression (10), mathematical expression (19) allows to determine the radius of the respective surface area in the respective recess 311, 312 covered by the respective photoresist structure 321, 322.

In the example of FIGS. 3A-3D, a hard mask is used in both etching steps to define the shape of the cavities at the wafer surface. In the first etching step, circular resist spots define cylindrical structures in the centers of the circles not covered by the hard mask. The radii of these cylinders depend on their position on the wafer according to the spatial dependence of the etching depth d_{etch}(R) to create cavities that are uniform in volume. After resist removal, the second etching stage lowers the structure created in the first stage. The second stage ensures that the shape of the cavity at the silicon interface, later defining the shape of the dome structure is independent from the structure compensating the spatial etching depth variation. One advantage of using a cylindrical structure at the cavity bottom is that all cavities on the wafer have the same diameter after opening the cavities from the back of the wafer by wet or dry etching. Furthermore, the alignment of the mask defining the resist spots against the circular voids in the hard mask is uncritical.

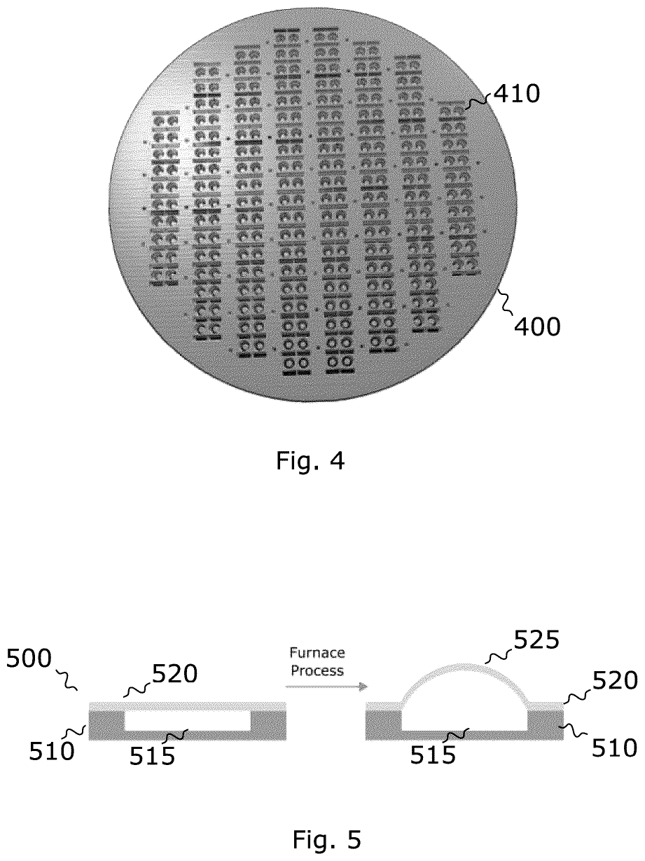

A perspective view of a wafer 400 with a plurality of cavities 410 formed as described above with respect to FIGS. 3A-3D are illustrated in FIG. 4.

FIGS. 2D and 3D further highlight that the method 100 may optionally further comprise removing 112 the patterned hard mask 210/310 after performing the second etch process. The patterned hard mask may be removed using various techniques such as wet chemical etching, dry etching (plasma etching) or a lift-off technique. Removing 112 the hard mask leaves a clean semiconductor wafer surface for subsequent fabrication steps.

Example subsequent fabrication steps of the method 100 will be described in the following with respect to FIG. 1 and FIG. 5. The method 100 may further comprise forming 114 a bonded wafer stack after removing the patterned hard mask by bonding the semiconductor wafer to a glass wafer. This is exemplarily illustrated in the left part of FIG. 5. The semiconductor wafer 510 is bonded to a glass wafer 520 to form the bonded wafer stack 500. For reasons of simplicity only a single cavity 515 is shown in the semiconductor wafer 510. The glass wafer 520 is a thin, typically circular piece of glass material.

Bonding the semiconductor wafer 510 to the glass wafer 520 may, e.g., comprise aligning and bonding the semiconductor wafer 510 to the glass wafer 520. Bonding may be achieved through various techniques such as anodic bonding, adhesive bonding, or thermal compression bonding. This creates a composite wafer stack, with the semiconductor wafer 510 on one side and the glass wafer 520 on the other. The glass material may be any type of glass material having a Coefficient of Thermal Expansion (CTE) similar to the CTE of the semiconductor wafer 510. For example, the glass material may be sodium-containing glass like borosilicate glass. The diameter of the glass wafer 520 may be identical to the diameter of the semiconductor wafer 510 (e.g., between approx. 100 mm and approx. 300 mm), however, need not be identical. The thickness of the glass wafer 520 may be identical or different from the thickness of the semiconductor wafer 510. It is to be noted that the present disclosure is no limited to the foregoing example materials and dimensions of the glass wafer 520. Other suitable glass materials and dimensions may be used as well. The pressure used for bonding the semiconductor wafer 510 to the glass wafer 520 may, e.g., be between 0 bar and 3 bar, in particular 2 bar. The semiconductor wafer 510 may, e.g., be bonded to the glass wafer 520 at a temperature between 300° C. and 500° C., in particular 330° C.

The method 100 may further comprise forming 116 dome-shaped structures in the glass wafer at the positions of the cavities by subjecting the bonded wafer stack to a furnace process. The dome-shaped structures are convex structures, meaning they curve outward, forming a dome-like shape that protrudes from the surface of the glass wafer and, hence, the bonded wafer stack. The dome-shaped structures are positioned directly over the cavities in the semiconductor wafer. The size and curvature of each dome-shaped structure correspond to the underlying cavity's dimensions. This is exemplarily illustrated in the right part of FIG. 5. In the furnace process, controlled heating causes the glass wafer 510 to soften and the pressure of the gas encapsulated in the cavities such as the cavity 515 increases. The encapsulated gas deforms the soft glass wafer at the positions corresponding to the cavities such as the cavity 515 in the semiconductor wafer 510 to form the dome-shaped structures. An example dome-shaped structure 525 at the position of the cavity 515 is illustrated in FIG. 5. The furnace process may use a temperature between 700° C. and 900° C., in particular 750° C.

The uniform cavity depths across the semiconductor wafer lead to more consistent heights of the dome-shaped structures. With more consistent heights of the dome-shaped structures, the physical dimensions of the optical package are within more narrow specifications. Additionally, the optical aberrations introduced by the optical package are reduced and within a smaller range. This may increase the yield.

These dome-shaped structures may act as lenses or protective covers for underlying features such as MEMS devices or other photonic or optical devices. In the following, two example approaches for further processing the bonded wafer stack will be described with reference to FIG. 1.

According to the first approach, the method 100 may further comprise removing 118 the semiconductor wafer from the glass wafer after forming the dome-shaped structures. In other words, the two wafers are carefully separated without damaging the dome-shaped structures in the glass wafer. For example, techniques like chemical etching, mechanical separation, or other processes designed to release the bond without damaging the glass wafer or the dome-shaped structures may be used.

The method 100 may further comprise in the first approach bonding 120 optical MEMS devices to the glass wafer after removing the semiconductor wafer from the glass wafer. The dome-shaped structures cover the optical MEMS devices. For example, the optical MEMS devices may be aligned and bonded to the glass wafer. The bonding process ensures precise placement and secure attachment of the optical MEMS devices under the dome-shaped structures. The dome-shaped structures provide a robust physical barrier, protecting the delicate optical MEMS devices from mechanical damage and environmental contaminants such as dust or moisture. Furthermore, the dome-shaped structures may act as lenses, focusing or directing light onto or from the optical MEMS devices, enhancing their optical performance.

Forming the dome-shaped structures and bonding the optical MEMS devices in sequential steps may streamline the manufacturing process allow to easily control it.

In the alternative second approach, the method 100 may further comprise forming 122 openings in the semiconductor wafer at the positions of the cavities after forming the dome-shaped structures. The openings in the semiconductor wafer extend from a second surface of the semiconductor wafer to the cavities. The second surface is opposite to the surface of the semiconductor wafer. The openings may, e.g., be formed in another etch process (e.g., using DRIE) or by laser drilling such that precise openings are formed in the semiconductor wafer that extend from the second surface (the backside) of the wafer to the pre-formed cavities.

The method 100 may further comprise in the second approach bonding 124 optical MEMS devices to the second surface of the semiconductor wafer after forming the openings in the semiconductor wafer. The dome-shaped structures cover the optical MEMS devices. For example, the optical MEMS devices may be aligned and bonded to the semiconductor wafer. The Also according the second approach, the dome-shaped structures provide a robust physical barrier, protecting the delicate optical MEMS devices from mechanical damage and environmental contaminants such as dust or moisture. Furthermore, the dome-shaped structures may act as lenses, focusing or directing light onto or from the optical MEMS devices, enhancing their optical performance.

The main difference between the first approach and the second approach lies in the placement and integration of the optical MEMS devices. In the first approach, the optical MEMS devices are bonded to the glass wafer after removing the semiconductor wafer, while in the second approach, the optical MEMS devices are bonded to the second surface of the semiconductor wafer through openings that extend to the cavities, with the dome-shaped structures in the glass wafer covering these devices.

The optical MEMS devices may be any type of miniaturized system that combines optical components with microelectromechanical elements. These optical MEMS devices integrate photonic and mechanical functionalities on a microscopic scale to manipulate light and perform various optical functions. For example, the optical MEMS devices may be MEMS laser beam scanning devices. The MEMS laser beam scanning devices are miniature devices that use microfabricated mechanical structures to direct and manipulate laser beams (e.g., with high precision). These MEMS laser beam scanning devices integrate optical components with MEMS technology to achieve precise control over the position, direction, and movement of laser beams for various applications (e.g., Light Detection and Ranging, LiDAR, or medical imaging).

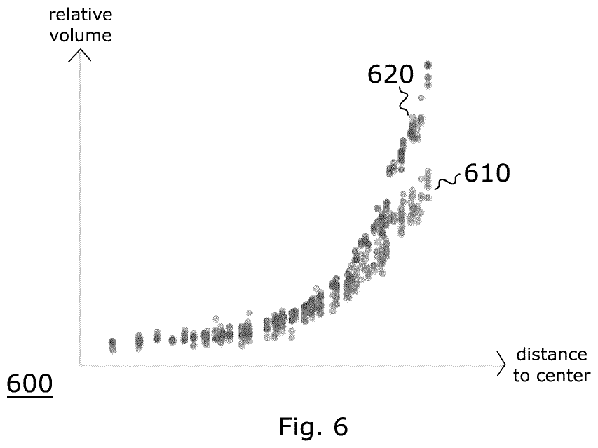

As described above, the method 100 allows to achieve more uniform cavity depths across the semiconductor wafer. This is further highlighted in diagram 600 illustrated in FIG. 6. The diagram 600 illustrates a comparison of the variation of the relative volumes of the cavities across the semiconductor wafer between the method 100 and a conventional method. The abscissa denotes the distance of the respective cavity to the center of the semiconductor wafer in arbitrary units. The ordinate denotes the relative volume of the respective cavity.

The data points 610 represent the relative volumes of cavities formed in in a semiconductor wafer according to method 100 described above. As a reference, the data points 620 represent the relative volumes of cavities formed in a semiconductor wafer according to a conventional method. The semiconductor wafers are identical for both methods.

As can be seen from FIG. 6, the relative volumes of the cavities across the semiconductor wafer vary (differ) less when formed with the method 100. This is due to the more uniform cavity depths across the semiconductor wafer achieved with the method 100.

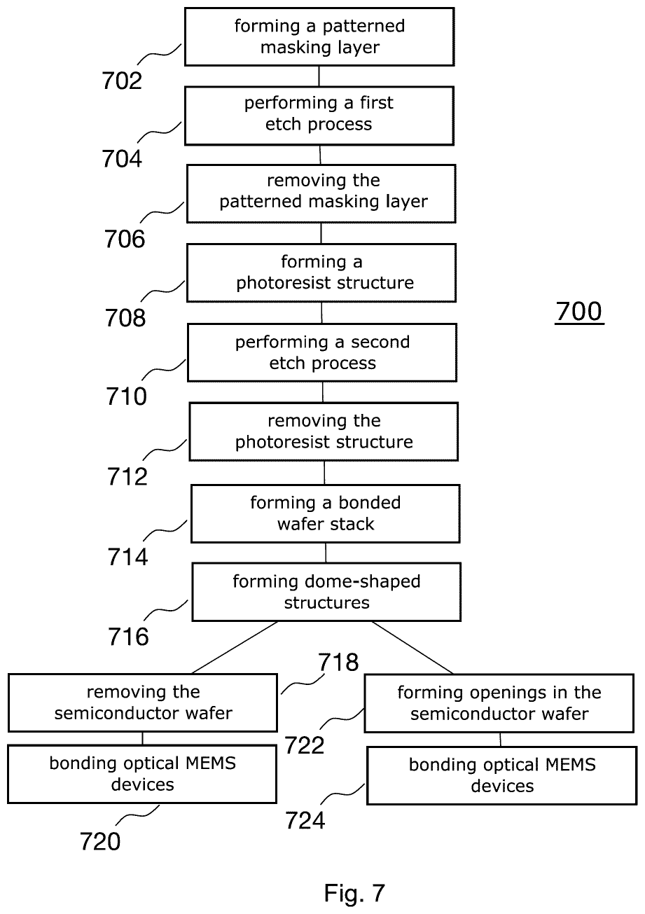

An alternative method 700 for forming a semiconductor package will be described in the following with reference to FIG. 7.

The method 700 comprises forming 702 a patterned masking layer on a surface of a semiconductor wafer. The patterned masking layer comprises a plurality of recesses defining positions of cavities to be formed in the semiconductor wafer.

The patterned masking layer is a patterned material layer applied to the surface of the semiconductor wafer that is used to pattern the cavities that are to be formed in the semiconductor wafer. For example, the patterned masking layer may be a patterned hard mask as used in the above described method 100. In alternative examples, the patterned masking layer may be a patterned photoresist. The patterned photoresist is made of a light-sensitive material that undergoes chemical changes when exposed to light. For example, positive photoresist or negative photoresist may be used. The patterned photoresist may, e.g., be formed by (using) spin coating. Forming the patterned photoresist by spin coating may, e.g., comprise dispensing (a predefined amount of) liquid photoresist material onto the center of the semiconductor wafer, spinning the semiconductor wafer (e.g., with a rotation speed between 1000 to 6000 rounds per minute) to spread the photoresist material uniformly across the semiconductor wafer, soft baking the spread photoresist material, patterning the photoresist material using a photomask that comprises the desired pattern that defines where the patterned photoresist will be formed, developing the photoresist to remove the exposed or unexposed areas of the photoresist (depending on the type of photoresist) and reveal the areas of the semiconductor wafer that are to be etched.

The method 700 further comprises performing 704 a first etch process (first etching process) after forming the patterned masking layer. In the first etch process, the semiconductor wafer is etched in the plurality of recesses to form hollows (deepenings, gaps, depressions) in the surface of the semiconductor wafer. The patterned masking layer covers the areas of the semiconductor wafer that are protected during the first etch process. Areas of the semiconductor wafer's surface not covered by the patterned masking layer are etched to a certain depth in the first etch process such that the hollows are formed in the surface of the semiconductor wafer. For example, DRIE may be used in the first etch process for etching the semiconductor wafer.

In addition, the method 700 comprises removing 706 the patterned masking layer after performing the first etch process. The patterned masking layer may be removed using various techniques such as chemical stripping, plasma ashing, (wet) chemical etching, dry etching (plasma etching) or a lift-off technique. After removing 706 the patterned masking layer, the areas of the semiconductor wafer that were protected during the first etch process are exposed.

The method 700 comprises forming 708 a photoresist structure after removing the patterned masking layer. The photoresist structure partly covers the surface of the semiconductor wafer in the hollows. A size of the surface area covered by the photoresist structure in the respective hollow is dependent on a position of the respective hollow in the semiconductor wafer. In other words, the photoresist structure is applied so that it partly covers the surface of the wafer within the previously etched hollows. The photoresist structure extends to boundaries of the hollows. The photoresist structure does not cover the semiconductor wafer in the centers of the hollows. That is, the edges of the hollows are covered (protected) by the photoresist structure, but the center areas are left exposed. For example, inner contours of the photoresist structure in the hollows may exhibit the same shape as the boundaries of the hollows. This means that the pattern of the photoresist inside the hollow may closely match the shape of the hollow itself, ensuring that the coverage is precise and consistent. The size of the area covered by the photoresist in each hollow is controlled and varies depending on the of the hollow on the wafer. Different hollows may have different amounts of coverage by the photoresist.

The photoresist structure is made of a light-sensitive material that undergoes chemical changes when exposed to light. For example, positive photoresist or negative photoresist may be used. The photoresist structure may be formed by (using) spray coating. Forming 708 the photoresist structure by spray coating may, e.g., comprise spraying liquid photoresist material through a nozzle under controlled pressure on the surface of the semiconductor wafer, soft baking the sprayed photoresist material, patterning the photoresist material using a photomask that comprises the desired pattern that defines where the photoresist structure will be formed, developing the photoresist to remove the exposed or unexposed areas of the photoresist (depending on the type of photoresist) and reveal the areas of the semiconductor wafer that are to be etched.

The method 700 comprises performing 710 a second etch process (second etching process) after forming the photoresist structure. In the second etch process, the semiconductor wafer is etched in the hollows at positions not covered by the photoresist structure to form the cavities. In other words, the semiconductor wafer is further etched within the hollows, but only in the areas exposed by the photoresist structure. This additional etching deepens the hollows to form the final cavities. The photoresist acts as a protective mask during this second etch process, preventing certain areas within the hollows from being etched further. For example, DRIE may be used in the second etch process for etching the semiconductor wafer.

By varying the size of the surface area covered by the photoresist structure in the respective hollow, the method 700 compensates for potential etching depth variations across the semiconductor wafer, in particular from the center to the edge of the semiconductor wafer, leading to (more) uniform cavity depths. Like the method 100, the method 700 allows to achieve (more) uniform cavity depths across the semiconductor wafer which is beneficial for the consistent performance of the optical devices packaged within these cavities. For example, the depths of the cavities may differ by less than 15% or less than 10% from each other across the semiconductor wafer. In particular, the depths of the cavities may differ by less than 15% or less than 10% particular from the center to the edge of the semiconductor wafer. The depths of the cavities may be at least 20%, 25% or 30% and at maximum 75%, 80% or 85% of the thickness of the semiconductor wafer. For example, if the thickness of the semiconductor wafer is between 400 μm and 1000 μm, the depths of the cavities may be between 100 and 600 μm, in particular 400 μm, with a depth variation of less 15% or less than 10% across the semiconductor wafer (in particular from the center to the edge of the semiconductor wafer). Overall, the method 700 allows to create well-defined cavities in semiconductor wafers, which is beneficial for high-precision optical packages used in various technological applications.

The photoresist structure may cover further parts of the semiconductor wafer. For example, the photoresist structure may be formed to cover sidewalls of the hollows. The sidewalls are the vertical or sloped surfaces of the hollows that were etched into the semiconductor wafer in the first etch process. If the sidewalls of the hollows are covered with photoresist (e.g., by the photoresist structure), the surfaces are protected during the second etch process. Accordingly, only the bottom of the hollows will be etched further, not the sides. This helps to maintain the shape and integrity of the hollow's sidewalls.

Alternatively or additionally, the photoresist structure may be formed to cover the surface of the semiconductor wafer at positions covered by the patterned masking layer in the first etch process. Essentially, this means the photoresist structure is applied to areas of the semiconductor wafer that were not etched in the first step. This helps to protect these regions from unwanted etching.

Analogously to what is described above for the method 100, the plurality of recesses in the patterned masking layer may exhibit the same dimensions. In other words, all recesses may have uniform dimensions in terms of form (shape), size and depth. Accordingly, the cavities may be formed with uniform dimensions in terms of shape and size. For example, the plurality of recesses may exhibit a circular form or an elliptic form. Accordingly, the cavities may exhibit a circular form or an elliptic form. However, the present disclosure is not limited thereto. The recesses may in general exhibit any form. The lateral extension (e.g., the horizontal dimension or width) of the respective cavity in the semiconductor wafer may be between 3 mm and 10 mm, in particular 5 mm.

According to examples of the present disclosure, the size of the surface area covered by the photoresist structure in the respective hollow may vary from the center to the edge of the semiconductor wafer. In other words, the size of the photoresist-covered area is not uniform across the semiconductor wafer. Instead, it changes progressively across the semiconductor wafer (e.g., from the center of the semiconductor wafer to its edge). In particular, the size of the surface area covered by the photoresist structure in the respective hollow may vary from the center to the edge of the semiconductor wafer to compensate the etching depth variation from the center to the edge of the semiconductor wafer in the first and the second etch process. By varying the photoresist coverage, the method 700 compensates analogously to the method 100 for variations in etching depth that naturally occur from the center to the edge of the semiconductor wafer. This ensures more uniform cavity depths across the entire semiconductor wafer. The size of the surface area covered by the photoresist structure in the respective hollow may, e.g., increase from the center to the edge of the semiconductor wafer. In other words, the size of the surface area covered by the photoresist structure in the respective hollow increases as one moves from the center of the semiconductor wafer towards its edge. This variation compensates for typically faster etching rates at the semiconductor wafer edge, ensuring uniform cavity depths.

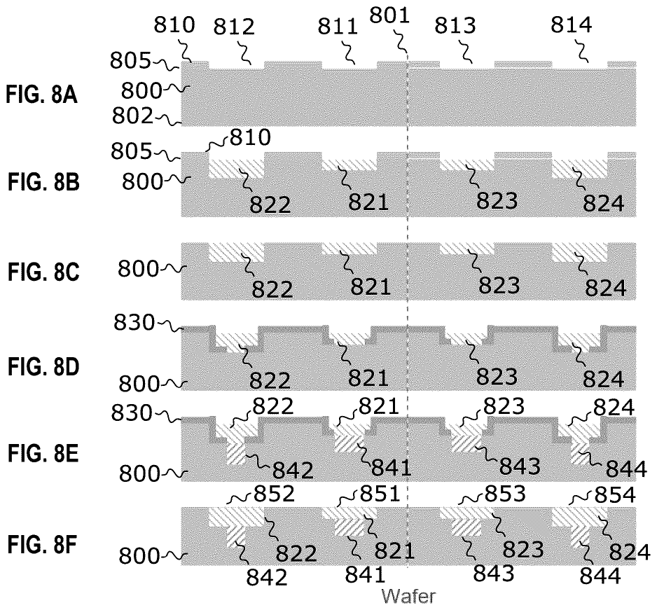

Further details of the method 700 will be described in the following with reference to FIGS. 8A-8F show a semiconductor wafer 800 during different stages of the method 700. FIGS. 8A-8F illustrate a sectional view through the semiconductor wafer 800. The dashed line 801 indicates the center of the semiconductor wafer 800 (with a radial distance R=0).

As shown in subfigure (a), the patterned masking layer 810 is initially formed on the surface 805 of the semiconductor wafer 800. For reasons of simplicity, the patterned masking layer 810 comprises only four recesses 811, . . . , 814. However, it is to be noted that the present disclosure is not limited thereto. Any number K≥2 of recesses may be formed in the patterned masking layer 810. The recesses 811 and 813 are in the center of the semiconductor wafer 800. The recess 811 is closer to the center of the semiconductor wafer 800 than the recess 812. The recess 812 is closer to the edge 802 of the semiconductor wafer 800 than the recess 811. Analogously, the recess 813 is closer to the center of the semiconductor wafer 800 than the recess 814. The recesses 811, . . . , 814 exhibit a circular form and the same dimensions in the example of FIGS. 8A-8F. In particular, the radius of the recesses 811, . . . , 814 is constant (the same).

Then, as shown in subfigure (b), the first etch process is performed to etch the semiconductor wafer 800 in the recesses 811, . . . , 814, e.g., at the positions not covered by the patterned masking layer 810. For example, DRIE may be used for etching the semiconductor wafer 800 in the first etch process. A hollow is formed in the first etch process as first part of the respective cavity by removing part of the semiconductor wafer 800 in the recesses 811, . . . , 814. The parts of the semiconductor wafer 800 etched away in the first etch process are denoted by reference signs 821, . . . , 824. A cylindrical first sub-cavity is formed in each of the recesses 811, . . . , 814 in the first etch process.

As indicated in subfigure (b), the depths of the hollows 821, . . . , 824 formed in the first etch process are not uniform across the semiconductor wafer 800. The depths of the hollows 821, . . . , 824 formed in the first etch process depend on the radial distance R to the center of the semiconductor wafer 800. In particular, the depth increases with increasing radial distance R to the center of the semiconductor wafer 800. The hollow 822 formed in the recess 812 is deeper than the hollow 821 formed in the recess 811. Similarly, the hollow 824 formed in the recess 814 is deeper than the hollow 823 formed in the recess 813. As the recesses 811 and 813 are positioned at the same radial distance to the center of the semiconductor wafer 800, the depths of the hollows 821 and 823 are substantially identical. Similarly, as the recesses 812 and 814 are positioned at the same radial distance to the center of the semiconductor wafer 800, the depths of the hollows 822 and 824 are substantially identical.

Then, after performing the first etch process, the patterned masking layer 810 is removed. This is illustrated in subfigure (c).

After removing the patterned masking layer 810, a photoresist structure 830 is formed. This is illustrated in subfigure (d). The photoresist structure 830 covers the surface 805 of the semiconductor wafer 805 at positions covered by the patterned masking layer 810 in the first etch process. In other words, the photoresist structure 830 covers the parts of the surface 805 of the semiconductor wafer 805 in which the hollows 821, . . . , 824 are not formed.

The photoresist structure 830 partly covers the surface 805 of the semiconductor wafer 800 in the hollows 821, . . . , 824. The photoresist structure 830 covers the boundaries of the hollows 821, . . . , 824. In other words, the photoresist structure 830 extends to the boundaries of the hollows 821, . . . , 824. The photoresist structure 830 further covers the sidewalls of the hollows 821, . . . , 824. The photoresist structure 830 does not cover the semiconductor wafer 800 in the centers of the hollows 821, . . . , 824. The inner contours of the photoresist structure 830 in the hollows 821, . . . , 824 exhibit the same shape as the boundaries of the hollows 821, . . . , 824. As the recesses 811, . . . , 814 and, hence, the hollows 821, . . . , 824 exhibit a circular form in the example of FIGS. 8A-8F, the photoresist structure 830 forms annular rings in the hollows 821, . . . , 824.

As can be seen from subfigure (d), the size of the surface area covered by the photoresist structure 830 in the respective hollow 821, . . . , 824 is dependent on the position of the respective hollow 821, . . . , 824 in the semiconductor wafer 800. In particular, the size of the surface area covered by the respective photoresist structure 830 in the respective hollow 821, . . . , 824 increases from the center to the edge of the semiconductor wafer 800. The photoresist structure 830 covers more of the surface area in the hollow 822 than in the hollow 821. Analogously, the photoresist structure 830 covers more of the surface area in the hollow 824 than in the hollow 823. As the recesses 811 and 813, and, hence, the hollows 821 and 823 are positioned at the same radial distance to the center of the semiconductor wafer 800, the surface areas covered in the hollows 821 and 823 by the photoresist structure 830 are substantially identical. Similarly, as the recesses 812 and 814, and, hence, the hollows 822 and 824 are positioned at the same radial distance to the center of the semiconductor wafer 800, the surface areas covered in the hollows 822 and 824 by the photoresist structure 830 are substantially identical.

As illustrated in subfigure (e), the second etch process is performed after forming the photoresist structure 830. For example, DRIE may be used for etching the semiconductor wafer 800 in the second etch process. In the second etch process, the semiconductor wafer 800 is etched in the hollows 821, . . . , 824 at positions not covered by the photoresist structure 830. Accordingly, a second part of the respective cavity is formed in the second etch process by removing part of the semiconductor wafer 800 in the recesses 821, . . . , 824. The parts of the semiconductor wafer 800 etched away in the second etch process are denoted by reference signs 841, . . . , 844. A cylindrical second sub-cavity is formed in each of the recesses 811, . . . 814 in the second etch process.

As indicated in subfigure (e), the depths of the structures (second sub-cavities) formed in the second etch process are not uniform across the semiconductor wafer 800. The depths of the structures formed in the second etch process depend on the radial distance R to the center of the semiconductor wafer 800. In particular, the depth increases with increasing radial distance R to the center of the semiconductor wafer 800.

The resulting cavities 851, . . . , 854 are shown in subfigure (f). The cavity 852 is deeper than the cavity 851. Analogously, the cavity 854 is deeper than the cavity 853. As the recesses 811 and 813, and, hence, the hollows 821 and 823 are positioned at the same radial distance to the center of the semiconductor wafer 800, the depths of the cavities 851 and 853 are substantially identical. Similarly, as the recesses 812 and 814, and, hence, the hollows 822 and 824 are positioned at the same radial distance to the center of the semiconductor wafer 800, the depths of the cavities 852 and 854 are substantially identical.

In the example of FIGS. 8A-8F, the etching depth variation is compensated by structuring cavities with smaller diameters. The cavity structures formed in the second etching step are radius dependent. The step-like structure etched in the example of FIGS. 8A-8F create cavities of varying diameters after opening the cavities from the wafer back. The fact that during the opening process no structures are released may reduce the defect density.

Analogously to the removal of the patterned hard masks 210/310 in the examples of FIGS. 2A-2D and FIGS. 3A-3D, FIG. 8F highlights that the method 700 may optionally further comprise removing 712 the photoresist structure 830 after performing the second etch process. The photoresist structure 830 may be removed using various techniques such as chemical stripping, plasma ashing or wet chemical etching. Removing 712 the photoresist structure 830 leaves a clean semiconductor wafer surface for subsequent fabrication steps.

For example, the method 700 may further comprise forming 714 a bonded wafer stack after removing the photoresist structure by bonding the semiconductor wafer to a glass wafer and

forming 716 dome-shaped structures in the glass wafer at the positions of the cavities by subjecting the bonded wafer stack to a furnace process. This may be done analogously to what is described above for the method 100.

The method 700 may comprise further features of the method 100 described above. For example, the method 700 may further comprise removing 718 the semiconductor wafer from the glass wafer after forming the dome-shaped structures and bonding 720 optical MEMS devices to the glass wafer after removing the semiconductor wafer from the glass wafer. The dome-shaped structures cover the optical MEMS devices. Alternatively, the method 700 may further comprise forming 722 openings in the semiconductor wafer at the positions of the cavities after forming the dome-shaped structures. The openings in the semiconductor wafer extend from a second surface of the semiconductor wafer to the cavities. The second surface is opposite to the surface of the semiconductor wafer. The method 700 may then additionally comprise bonding 724 optical MEMS devices to the second surface of the semiconductor wafer after forming the openings in the semiconductor wafer. The dome-shaped structures cover the optical MEMS devices. Details of these optional further features of the method 700 are given above with reference to the method 100.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:

Aspect 1: A method for forming an optical package, the method comprising: forming a patterned hard mask on a surface of a semiconductor wafer, wherein the patterned hard mask comprises a plurality of recesses defining positions of cavities to be formed in the semiconductor wafer; forming photoresist structures, including forming a respective photoresist structure on the surface of the semiconductor wafer in each recess of the plurality of recesses, wherein a size of a surface area covered by the respective photoresist structure in a respective recess of the plurality of recesses is dependent on a position of the respective recess on the semiconductor wafer; performing a first etch process, wherein, in the first etch process, the semiconductor wafer is etched in the plurality of recesses at positions not covered by the photoresist structure; removing the photoresist structures after performing the first etch process; and performing a second etch process after removing the photoresist structures, wherein, in the second etch process, the semiconductor wafer is etched in the plurality of recesses to form the cavities by lowering structures formed in the first etch process.

Aspect 2: The method of Aspect 1, wherein the size of the surface area covered by the respective photoresist structure in the respective recess varies from a center to an edge of the semiconductor wafer.

Aspect 3: The method of any of Aspects 1-2, wherein the size of the surface area covered by the respective photoresist structure in the respective recess varies from a center to an edge of the semiconductor wafer to compensate an etching depth variation from the center to the edge of the semiconductor wafer in the first etch process and the second etch process.

Aspect 4: The method of any of Aspects 1-3, wherein the size of the surface area covered by the respective photoresist structure in the respective recess increases from a center to an edge of the semiconductor wafer.

Aspect 5: The method of any of Aspects 1-4, wherein the photoresist structures exhibit the same shape as the plurality of recesses.

Aspect 6: The method of any of Aspects 1-5, wherein the photoresist structures are formed in the centers of the plurality of recesses.

Aspect 7: The method of any of Aspects 1-6, wherein the photoresist structures are spaced apart from boundaries of the plurality of recesses formed by the patterned hard mask.

Aspect 8: The method of any of Aspects 1-7, wherein the photoresist structures are formed at boundaries of the plurality of recesses and contact the patterned hard mask along an entire respective boundary, and wherein the photoresist structures do not cover the semiconductor wafer in the centers of the plurality of recesses.

Aspect 9: The method of Aspect 8, wherein inner contours of the photoresist structures exhibit the same shape as the boundaries of the plurality of recesses.

Aspect 10: The method of any of Aspects 1-9, further comprising: removing the patterned hard mask after performing the second etch process.

Aspect 11: The method of Aspect 10, further comprising: forming a bonded wafer stack after removing the patterned hard mask by bonding the semiconductor wafer to a glass wafer; and forming dome-shaped structures in the glass wafer at the positions of the cavities by subjecting the bonded wafer stack to a furnace process.

Aspect 12: A method for forming an optical package, the method comprising: forming a patterned masking layer on a surface of a semiconductor wafer, wherein the patterned masking layer comprises a plurality of recesses defining positions of cavities to be formed in the semiconductor wafer; performing a first etch process, wherein, in the first etch process, the semiconductor wafer is etched in the plurality of recesses to form hollows in the surface of the semiconductor wafer; removing the patterned masking layer; forming a photoresist structure after removing the patterned masking layer, wherein the photoresist structure partly covers the surface of the semiconductor wafer in the hollows, wherein a size of a surface area covered by the photoresist structure in a respective hollow of the hollows is dependent on a position of the respective hollow in the semiconductor wafer; and performing a second etch process, wherein, in the second etch process, the semiconductor wafer is etched in the hollows at positions not covered by the photoresist structure to form the cavities.

Aspect 13: The method of Aspect 12, wherein the patterned masking layer is a patterned hard mask.

Aspect 14: The method of any of Aspects 12-13, wherein the patterned masking layer is a patterned photoresist.

Aspect 15: The method of Aspect 14, wherein the patterned photoresist is formed by spin coating.

Aspect 16: The method of any of Aspects 12-15, wherein the photoresist structure is formed to cover sidewalls of the hollows.

Aspect 17: The method of any of Aspects 12-16, wherein the photoresist structure is formed to cover the surface of the semiconductor wafer at positions covered by the patterned masking layer in the first etch process.

Aspect 18: The method of any of Aspects 12-17, wherein the photoresist structure is formed by spray coating.

Aspect 19: The method of any of Aspects 12-18, wherein the size of the surface area covered by the photoresist structure in the respective hollow varies from a center to an edge of the semiconductor wafer.

Aspect 20: The method of any of Aspects 12-19, wherein the size of the surface area covered by the photoresist structure in the respective hollow varies from a center to an edge of the semiconductor wafer to compensate an etching depth variation from the center to the edge of the semiconductor wafer in the first etch process and the second etch process.

Aspect 21: The method of any of Aspects 12-20, wherein the size of the surface area covered by the photoresist structure in the respective hollow increases from a center to an edge of the semiconductor wafer.

Aspect 22: The method of any of Aspects 12-21, wherein the photoresist structure extends to boundaries of the hollows, and wherein the photoresist structure does not cover the semiconductor wafer in the centers of the hollows.

Aspect 23: The method of Aspect 22, wherein inner contours of the photoresist structure in the hollows exhibit the same shape as the boundaries of the hollows.

Aspect 24: The method of any of Aspects 12-23, further comprising: removing the photoresist structure after performing the second etch process.

Aspect 25: The method of Aspect 24, further comprising: forming a bonded wafer stack after removing the photoresist structure by bonding the semiconductor wafer to a glass wafer; and forming dome-shaped structures in the glass wafer at the positions of the cavities by subjecting the bonded wafer stack to a furnace process.

Aspect 26: The method of Aspect 11, further comprising: removing the semiconductor wafer from the glass wafer after forming the dome-shaped structures; and bonding optical MEMS devices to the glass wafer after removing the semiconductor wafer from the glass wafer, wherein the dome-shaped structures cover the optical MEMS devices.

Aspect 27: The method of Aspect 11, further comprising: forming openings in the semiconductor wafer at the positions of the cavities after forming the dome-shaped structures, wherein the openings in the semiconductor wafer extend from a second surface of the semiconductor wafer to the cavities, and wherein the second surface is opposite to the surface of the semiconductor wafer; and bonding optical MEMS devices to the second surface of the semiconductor wafer after forming the openings in the semiconductor wafer, wherein the dome-shaped structures cover the optical MEMS devices.

Aspect 28: The method of Aspect 26, wherein the optical MEMS devices are MEMS laser beam scanning devices.

Aspect 29: The method of Aspect 1, wherein deep reactive ion etching is used in the first etch process and the second etch process for etching the semiconductor wafer.

Aspect 30: The method of Aspect 1, wherein the plurality of recesses exhibit the same dimensions.

Aspect 31: The method of Aspect 1, wherein the plurality of recesses exhibit a circular or an elliptic form.

Aspect 32: The method of Aspect 1, wherein depths of the cavities are at least 25% and at maximum 80% of a thickness of the semiconductor wafer.

Aspect 33: The method of Aspect 1, wherein depths of the cavities differ by less than 15% from each other across the semiconductor wafer.

Aspect 34: The method of Aspect 1, wherein a lateral extension of the respective cavity in the semiconductor wafer is at maximum 10 mm.

Aspect 35: A system configured to perform one or more operations recited in one or more of Aspects 1-34.

Aspect 36: An apparatus comprising means for performing one or more operations recited in one or more of Aspects 1-34.

1. A method for forming an optical package, the method comprising:
forming a patterned hard mask on a surface of a semiconductor wafer, wherein the patterned hard mask comprises a plurality of recesses defining positions of cavities to be formed in the semiconductor wafer;
forming photoresist structures, including forming a respective photoresist structure on the surface of the semiconductor wafer in each recess of the plurality of recesses, wherein a size of a surface area covered by the respective photoresist structure in a respective recess of the plurality of recesses is dependent on a position of the respective recess on the semiconductor wafer;
performing a first etch process, wherein, in the first etch process, the semiconductor wafer is etched in the plurality of recesses at positions not covered by the photoresist structure;
removing the photoresist structures after performing the first etch process; and
performing a second etch process after removing the photoresist structures, wherein, in the second etch process, the semiconductor wafer is etched in the plurality of recesses to form the cavities by lowering structures formed in the first etch process.

2. The method of claim 1, wherein the size of the surface area covered by the respective photoresist structure in the respective recess varies from a center to an edge of the semiconductor wafer.

3. The method of claim 1, wherein the size of the surface area covered by the respective photoresist structure in the respective recess varies from a center to an edge of the semiconductor wafer to compensate an etching depth variation from the center to the edge of the semiconductor wafer in the first etch process and the second etch process.

4. The method of claim 1, wherein the size of the surface area covered by the respective photoresist structure in the respective recess increases from a center to an edge of the semiconductor wafer.

5. The method of claim 1, wherein the photoresist structures exhibit the same shape as the plurality of recesses.

6. The method of claim 1, wherein the photoresist structures are formed in the centers of the plurality of recesses.

7. The method of claim 1, wherein the photoresist structures are spaced apart from boundaries of the plurality of recesses formed by the patterned hard mask.

8. The method of claim 1, wherein the photoresist structures are formed at boundaries of the plurality of recesses and contact the patterned hard mask along an entire respective boundary, and wherein the photoresist structures do not cover the semiconductor wafer in the centers of the plurality of recesses.

9. The method of claim 8, wherein inner contours of the photoresist structures exhibit the same shape as the boundaries of the plurality of recesses.

10. The method of claim 1, further comprising:
removing the patterned hard mask after performing the second etch process.

11. The method of claim 10, further comprising:
forming a bonded wafer stack after removing the patterned hard mask by bonding the semiconductor wafer to a glass wafer; and
forming dome-shaped structures in the glass wafer at the positions of the cavities by subjecting the bonded wafer stack to a furnace process.

12. A method for forming an optical package, the method comprising:
forming a patterned masking layer on a surface of a semiconductor wafer, wherein the patterned masking layer comprises a plurality of recesses defining positions of cavities to be formed in the semiconductor wafer;
performing a first etch process, wherein, in the first etch process, the semiconductor wafer is etched in the plurality of recesses to form hollows in the surface of the semiconductor wafer;
removing the patterned masking layer;
forming a photoresist structure after removing the patterned masking layer, wherein the photoresist structure partly covers the surface of the semiconductor wafer in the hollows, wherein a size of a surface area covered by the photoresist structure in a respective hollow of the hollows is dependent on a position of the respective hollow in the semiconductor wafer; and
performing a second etch process, wherein, in the second etch process, the semiconductor wafer is etched in the hollows at positions not covered by the photoresist structure to form the cavities.

13. The method of claim 12, wherein the patterned masking layer is a patterned hard mask.

14. The method of claim 12, wherein the patterned masking layer is a patterned photoresist.

15. The method of claim 14, wherein the patterned photoresist is formed by spin coating.

16. The method of claim 12, wherein the photoresist structure is formed to cover sidewalls of the hollows.

17. The method of claim 12, wherein the photoresist structure is formed to cover the surface of the semiconductor wafer at positions covered by the patterned masking layer in the first etch process.

18. The method of claim 12, wherein the photoresist structure is formed by spray coating.

19. The method of claim 12, wherein the size of the surface area covered by the photoresist structure in the respective hollow varies from a center to an edge of the semiconductor wafer.

20. The method of claim 12, wherein the size of the surface area covered by the photoresist structure in the respective hollow varies from a center to an edge of the semiconductor wafer to compensate an etching depth variation from the center to the edge of the semiconductor wafer in the first etch process and the second etch process.

21. The method of claim 12, wherein the size of the surface area covered by the photoresist structure in the respective hollow increases from a center to an edge of the semiconductor wafer.

22. The method of claim 12, wherein the photoresist structure extends to boundaries of the hollows, and wherein the photoresist structure does not cover the semiconductor wafer in the centers of the hollows.

23. The method of claim 22, wherein inner contours of the photoresist structure in the hollows exhibit the same shape as the boundaries of the hollows.

24. The method of claim 12, further comprising:
removing the photoresist structure after performing the second etch process.

25. The method of claim 24, further comprising:
forming a bonded wafer stack after removing the photoresist structure by bonding the semiconductor wafer to a glass wafer; and
forming dome-shaped structures in the glass wafer at the positions of the cavities by subjecting the bonded wafer stack to a furnace process.

26. The method of claim 11, further comprising:
removing the semiconductor wafer from the glass wafer after forming the dome-shaped structures; and
bonding optical MEMS devices to the glass wafer after removing the semiconductor wafer from the glass wafer, wherein the dome-shaped structures cover the optical MEMS devices.

27. The method of claim 11, further comprising:
forming openings in the semiconductor wafer at the positions of the cavities after forming the dome-shaped structures, wherein the openings in the semiconductor wafer extend from a second surface of the semiconductor wafer to the cavities, and wherein the second surface is opposite to the surface of the semiconductor wafer; and
bonding optical MEMS devices to the second surface of the semiconductor wafer after forming the openings in the semiconductor wafer, wherein the dome-shaped structures cover the optical MEMS devices.

28. The method of claim 26, wherein the optical MEMS devices are MEMS laser beam scanning devices.

29. The method of claim 1, wherein deep reactive ion etching is used in the first etch process and the second etch process for etching the semiconductor wafer.

30. The method of claim 1, wherein the plurality of recesses exhibit the same dimensions.

31. The method of claim 1, wherein the plurality of recesses exhibit a circular or an elliptic form.

32. The method of claim 1, wherein depths of the cavities are at least 25% and at maximum 80% of a thickness of the semiconductor wafer.

33. The method of claim 1, wherein depths of the cavities differ by less than 15% from each other across the semiconductor wafer.

34. The method of claim 1, wherein a lateral extension of the respective cavity in the semiconductor wafer is at maximum 10 mm.
